(19) United States
(12) Patent Application Publication
(10) Pub. No.: US 2005/0282358 A1
(43) Pub. Date: Dec. 22, 2005

(54) Method for transferring an electrically active thin layer

(75) Inventors: Lea Di Cioccio, Saint Ismire (FR); Fabrice Letertre, Grenoble (FR); Elsa Hugonnard-Bruyere, Fuveau (FR)

Correspondence Address: OBLON, SPIVAK, MCCLELLAND, MAIER & NEUSTADT, P.C., 1940 DUKE STREET, ALEXANDRIA, VA, 22314, US

(73) Assignees: COMMISSARIAT A L'ENERGIE ATOMIQUE, Paris 15 eme (FR); S.O.I TEC SILICON ON INSULATOR TECHNOLOGIES, Crolles Cedex (FR)

(21) Appl. No.: 10/519,406

(22) PCT Filed: Jul. 15, 2003
(86) PCT No.: PCT/FR03/02225

§ 371 Date: Jan. 5, 2005

(30) Foreign Application Priority Data
Jul. 18, 2002 (FR) 02 09118

(51) Int. Cl. H01L 21/30; H01L 21/46

(52) U.S. Cl. 438/459

(57) ABSTRACT

A method for transferring an electrically active thin film from an initial substrate to a target substrate including: ion implantation through one face of the initial substrate to create a buried, embrittled film at a determined depth relative to the implanted face of the initial substrate, thus delimiting a thin film between the implanted face and the buried face; fastening the implanted face of the initial substrate with a face of the target substrate; separating the thin film from the remainder of the initial substrate at the level of the buried film; and thinning down the thin film transferred on the target substrate. The implantation dosage, energy, and current are chosen, during the ion implantation, so that concentration in implantation defects is less than a determined threshold, resulting in, within the thinned down thin film, a number of acceptor defects compatible with desired electrical properties of the thin film.

### TECHNICAL FIELD

The invention concerns a method for transferring an electrically active thin film from an initial substrate to a target substrate.

It applies, in particular, to the transfer of a thin film of semi-conductive material and notably to the transfer of a thin film of silicon carbide.

### STATE OF THE PRIOR ART

The document FR-A-2 681 472 (corresponding to American U.S. Pat. No. 5,374,564) teaches a method for producing thin films of semi-conductive material. The thin film is first delimited in an initial substrate by ion implantation. One face of the substrate is bombarded with ions (generally hydrogen ions) according to a determined dosage and energy in order to create a buried, embrittled film at a depth, in relation to the bombarded face, close to the average penetration depth of the ions in the substrate. The bombarded face of the substrate is then fastened with a face of a receiving substrate or stiffener. An annealing then makes it possible to obtain a separation of said thin film from the remainder of the initial substrate. One then obtains a thin film adhering to the stiffener. This technique is now well known and well mastered. It enables electronic quality SOI substrates to be obtained.

Said method has been applied, after several adaptations, to silicon carbide semi-conductor in order to obtain a stack of films called SiCOI and made up of a silicon substrate successively covered with a film of silicon oxide and a film of silicon carbide. One may refer to this subject in the article “Silicon carbide on insulator formation by the Smart-Cut® process by L. Di Cioccio et al., Materials Science and Engineering, B 46 (1997), pages 349 to 356.

Within the scope of these developments carried out on the SiCOI substrate, the problem of the electrical resistivity of the transferred thin film of SiC has been studied.

The first films of SiC transferred onto the silicon oxide had completely lost their electrical conductive properties, initially induced by an appropriate dosage, and had become completely isolating. It has been shown that the electrical compensation introduced into the transferred films and responsible for said acquired isolating property, is linked to the implantation defects created in the material by the passage of the protons used to carry out the implantation. One may refer to this subject in the following articles:
“Defect studies in Epitaxial SiC—6H Layers on Insulator (SiCOI)” by E. Hugonnard-Bruyère et al., Microelectronic Engineering 48 (1999), pages 277 to 280;
“High resistance layers in n-type 4K—silicon carbide by hydrogen ion implantation” by R. K. Nadella et al, Appl. Phys. Lett. 70(7), 17^{th} Feb. 1997, pages 886 to 888;
“Electrical isolation of GaN by ion implantation damage: Experiment and model” by C. Uzan-Saguy et al., Applied Physics Letters, Vol. 74, no 17, 26^{th} Apr. 1999, pages 2441 to 2443.

The high dosage of protons required to obtain the transfer of a thin film of SiC creates, over the whole path of said ions between the implantation surface and the average ion implantation depth, a concentration of implantation defects that behave, from an electrical point of view, as acceptor centres.

The initial doping of type n obtained, for example, by nitrogen dopant or type p obtained, for example, by aluminium dopant, of the thin films of SiC studied varies between 10¹⁹ atoms/cm³ and 10¹⁵ atoms/cm³. The doped thin films came either from an epitaxy or from the bulk substance itself. Simple reasoning shows that if the concentration of residual compensating centres in the transferred thin film, introduced by the method used, is greater than the initial doping (concentration of donor centres), the transferred thin film has a very resistive behaviour (see the article by E. Hugonnard-Bruyère cited above).

This concentration of acceptor defects depends firstly on the concentration of implantation defects created by the proton implantation and, secondly, on the capability of the technological steps applied to the transferred thin film to do away with said defects and thus reduce, as much as possible, their concentration.

From an electronic point of view, a thin semi-conductive film comprising compensator defects is not going to have the transport properties (concentration of carriers) suited to the production of an electronic device. Furthermore, it is imperative that after the formation of a SiCOI structure by the method taught by the document FR-A-2 681 472, the transferred film can be used to produce an electronic device.

Numerous teams have studied the generation of implantation defects as well as the conditions required for their annihilation. It follows from these studies that for SiC certain implantation defects created by light ions such as hydrogen can be stable at annealing temperatures up to 1500° C. even although, for dopings greater than 2.10¹⁸ atoms/cm³, annealing at around 1300° C. is sufficient to recover the initial resistivity (see the article by E. Hugonnard-Bruyère cited above). Nevertheless, under these production conditions, the residual electrical compensation remains high. The article “The effects of damage on hydrogen implant induced thin-film separation from bulk silicon carbide” by R. B. Gregory et al., Mat. Res. Soc. Symp. Proc. Vol. 572, 1999, Materials Research Society, pages 33 to 38, teaches that an implantation at high temperature makes it possible to heal part of the defects without however being able to do away with them completely.

Obviously, the fact of transferring, by this technique, a thin film of SiC onto a silicon substrate does not make it possible to apply such far reaching thermal treatments, since silicon melts at 1413° C.

Finally, in a general manner, even if the bonding film (or even the absence of bonding film) and the use of a substrate other than silicon (polycrystalline SiC, for example) allowed said thermal treatment, this would not suffice to recover a correct resistivity, given the high concentration of defects introduced and their thermal stability, and would not be desirable since said temperatures are little used in the microelectronics industry.

Finally, implantation at high temperature is difficult to implement in an industrial manner and does not make it possible to entirely recover the electrical conductivity corresponding to the initial doping.

### DESCRIPTION OF THE INVENTION

In order to overcome the disadvantages of the prior art, a manufacturing method is proposed herewith that makes it possible to obtain a film of semi-conductive material on a support with a residual electrical compensation, due to the ionic implantation, that is negligible.

The aim of the invention is therefore a method for transferring an electrically active thin film from an initial substrate to a target substrate, comprising the following steps:
ion implantation through one face of said initial substrate in order to create a buried, embrittled film at a determined depth in relation to the implanted face of the initial substrate, a thin film thus being delimited between the implanted face and the buried face,
fastening the implanted face of the initial substrate with a face of the target substrate,
separating the thin film from the remainder of the initial substrate at the level of the buried film,
thinning down the thin film transferred on the target substrate,
   characterised in that the implantation dosage, energy and current are chosen, during the ion implantation stage, so that the concentration of implantation defects is less than a determined threshold, resulting in, within the thinned down thin film, a number of defect acceptors that is compatible with the desired electrical properties of the thin film.

The ion implantation step may consist in implanting ions chosen from among hydrogen and rare gases.

The step of fastening may involve a bonding chosen from bonding by molecular adhesion via intermediate films or without intermediate films, bonding by reaction, metallic bonding, brazing or bonding by species diffusion.

Advantageously, a healing annealing of the implantation defects is carried out on the thin film. Said healing annealing may be carried out before or after the thinning down of the thin film.

The method according to the invention applies in particular to obtaining a thin film of SiC, GaAs, GaN, diamond or InP on a target substrate.

### BRIEF DESCRIPTION OF THE DRAWINGS

The invention will be more fully understood and other advantages and specific features will become clearer on reading the description that follows, given by way of indication and in nowise limitative, and by referring to the appended drawings amongst which:

FIG. 1 is a diagram representing the profile of acceptor defects in an implanted initial substrate,

FIG. 2 is a diagram representing the concentration of vacancies created as a function of the depth of the initial implanted substrate.

### DETAILLED DESCRIPTION OF SPECIFIC EMBODIMENTS

The number of acceptor defects in the transferred and thinned down thin film according to the present invention depends on the profile of defects that is created in the transferred thin film (distribution of defects according to the thickness of the thin film). Said profile of defects depends on the implantation energy. The choice of implantation conditions (implantation energy, thickness of the implantation mask) is crucial and makes it possible to define the thickness of the future active film.

The inventors have arrived at the conclusion that the profile of electrical compensator defects is proportional to the profile of the implantation defects. It is therefore necessary to generate, through the choice of the implantation conditions, a thin film that contains, after implantation, at least one zone with a profile of defects sufficiently flat so that the final residual concentration of defects is spread out in a homogeneous manner in the film that has to remain. The remainder of the transferred film, in which the profile of defects is no longer flat, is eliminated by thinning down.

The number of acceptor defects in the transferred and thinned down thin film according to the present invention also depends on the concentration of implantation defects created by the irradiation of protons. The parameter affecting the concentration of defects is the implantation dosage and the implantation current. The inventors of the present invention have observed that the implantation current makes it possible to play on the defect creation efficiency. Thus, implanting at low current density makes it possible to reduce the concentration of defects. The other parameter is the dosage of implanted ions. It is possible to reduce, in a significant manner, the dosage of implanted ions in the initial substrate by carrying out the implantation at high temperature or by playing on the channelling effect.

The number of acceptor defects in the transferred and thinned down thin film according to the present invention finally depends on the posterior annealing type (or healing) treatments. For silicon carbide in particular, certain implantation defects created by light ions such as hydrogen may be stable at annealing temperatures up to 1500° C.

According to this approach, the critical point that appears is the definition of the future active film (in other words, the film obtained after thinning down). Said film is completely defined by the profile of defects created by the passage of implanted ions as well as by the healing capability of the technological steps carried out after the fracture of the initial substrate.

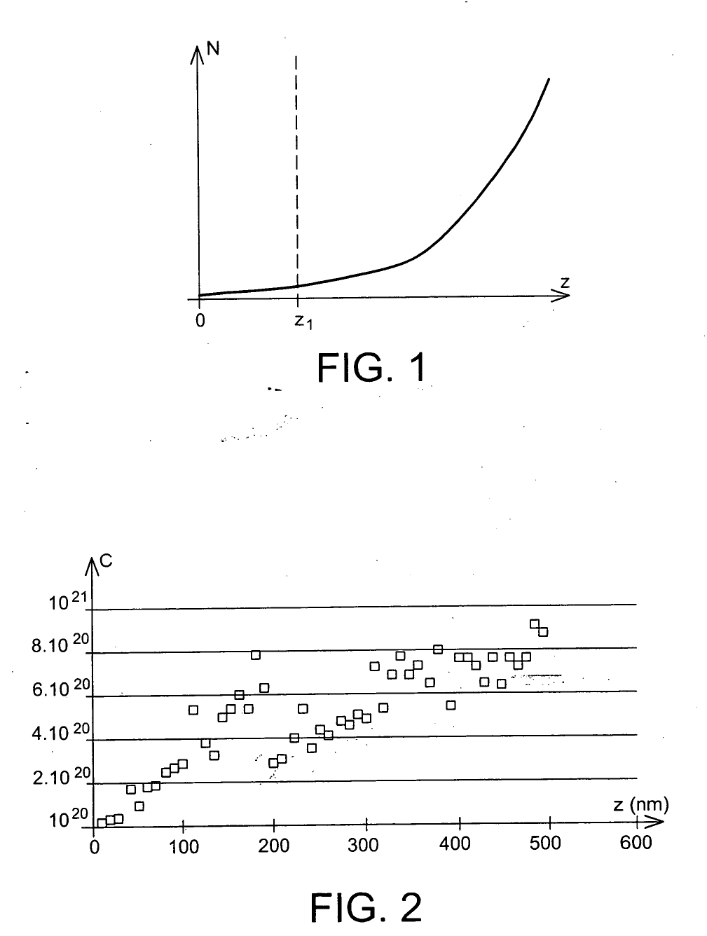

FIG. 1 is a diagram representing the profile of acceptor defects in an initial implanted substrate. The y axis represents the number N of acceptor defects. The x axis represents the depth z of the substrate from the implanted face (abscissa 0). The abscissa z₁ gives the thickness of the thin film after thinning down, making it possible to obtain a thin film with the desired electrical properties.

An empirical law linking the profile of the remaining electrical defects in the thin film with the profile of defects created during the implantation was able to be established. Said post-implantation profile may be given, with good accuracy, by the TRIM software, making it possible to simulate the creation of elementary crystalline defects (C and Si vacancies in the case of silicon carbide) during the ion implantation step.

FIG. 2 is a diagram representing the concentration C of vacancies created (in atoms/cm³) as a function of the depth z of the substrate from the implanted face (abscissa 0). This diagram was obtained by simulation using the TRIM software for silicon carbide implanted with H⁺ ions (implantation energy 180 keV, implantation dosage 6.5.10¹⁶ ions.cm²). For an implantation energy of 180 keV, the average implantation depth Rₚ is greater than 1100 nm.

Hall effect measurements were carried out for an initial substrate in SiC and for said implantation conditions. They gave an average residual concentration of acceptor defects of 4.10¹⁶ atoms/cm³ for a film of SiC of 0.5 μm thickness. The TRIM simulation indicates that the concentration of defects present in the first 0.5 μm of the implanted film is always less than 9.10²⁰ atoms/cm³. The concentration of defects in said film is less, at all points, than the maximum concentration of 9.10²⁰ atoms/cm³. This means that, at the end of the method according to the invention, the final concentration of residual defects will always be less than 9.10²⁰ K. Thanks to the electrical measurement giving an average concentration in all of the film, one can estimate the coefficient K linking the created physical defects and the residual electrical defects:
K=4.10¹⁶/9.10²⁰=4.5. 10⁻⁵
with the relation C_{f}=K.Cᵢ.

Cᵢ is the average concentration of primary implantation defects and depends on the way the implantation is carried out in the material (in other words, its implantation profile). C_{f} is the average concentration of final electrical defects in the thin film after transfer and annealing. K is a proportionality coefficient linked to the annealing steps (healing of defects).

For a hydrogen implantation carried out without intentional heating in the SiC through a layer of SiO₂ less than 50 nm, for an energy of 180 keV, a dosage of 6.5.10¹⁶ atoms/cm³ and a maximum thermal budget of the transferred thin film of 1350° C. for 48 hours, the coefficient K is equal to around 4.5.10⁻⁵. This signifies that the method employed makes it possible to reduce by a factor of 2.25.10⁴ the concentration of created defects.

We will now describe one embodiment of the method according to the present invention, which makes it possible to obtain a transferred thin film of SiC with a final thickness less than or equal to 0.5 μm.

A flat surface of an initial substrate of monocrystalline SiC is mechanically and chemically polished. One grows by epitaxy a thin film of SiC at the desired doping level (for example, 10¹⁷ atoms of impurity/cm³) on the polished face of the substrate. Said step is only necessary if one wishes to transfer a thin film with a doping less than the residual doping of a substrate or having a better crystalline quality. The epitaxied film may receive a mechanical polishing or a mechanical/chemical polishing in order to obtain a surface that allows molecular adhesion. One then carries out a thermal oxidation in order to obtain an oxide film with a thickness of 50 nm. A variation consists in depositing an oxide over a thickness not exceeding 50 nm.

The oxidised face of the initial substrate is subjected to a hydrogen implantation at an energy of 180 keV and a dosage of 6.5.10¹⁶ atoms/cm³ in order to create an embrittled film delimiting the thin film to be transferred. It is possible to reduce, in a significant manner, this limit dosage by implanting hydrogen at high temperature. For example, at an implantation temperature of around 650° C., the critical dosage goes from 6.5.10¹⁶ to round 4.5.10¹⁶ atoms/cm³. Said implantation is carried out in order to generate over the first 500 nm of the film of SiC a simulated concentration of defects less than 9.10²⁰ atoms/cm³.

The surface of the implanted oxide is cleaned, as is the surface of oxide present on the target substrate. Said surfaces are then specifically activated, for example by mechanical/chemical polishing. The surfaces thus treated are then bonded by molecular adhesion.

One then carries out the transfer of the delimited thin film by provoking a fracture within the initial substrate, at the level of the embrittled zone. The fracture may be obtained by a suitable thermal treatment.

The thin film transferred on the target substrate is annealed at very high temperature (1350° C.). An oxidising annealing makes it possible to consume by oxidation, in a controlled manner, the thin film of SiC, to exo-diffuse the hydrogen present in the thin film and to heal the implantation defects. The annealing time is such as to heal the implantation defects. It may be 48 hours.

One then carries out the de-oxidisation of the thin film of SiC.

The thin film is then thinned down by ion beam etching or by thermal oxidation in order to adjust the thin film to the desired thickness (less than 0.5 μm). Said step may be carried out before the step of annealing at very high temperature.

The method according to the invention may be applied to any material that one wishes to transfer by the Smart-Cut® method but in which the electrical resistivity later poses a problem (SiC, GaAs, InP, GaN, diamond, for example).

Other bonding methods apart from molecular adhesion via intermediate oxide films may be used: molecular adhesion without intermediate films, bonding by reaction, metallic bonding, brazing or bonding by diffusion of species. The ion implantation may be carried out with other ion species apart from hydrogen, for example helium.

1-7. (canceled)

8. A method for transferring an electrically active thin film from an initial substrate to a target substrate, comprising:
ion implantation through one face of the initial substrate to create a buried, embrittled film at a determined depth in relation to the implanted face of the initial substrate, a thin film thus being delimited between the implanted face and the buried face;
fastening the implanted face of the initial substrate with a face of the target substrate;
separating the thin film from a remainder of the initial substrate at a level of the buried film; and
thinning down the thin film transferred on the target substrate;
wherein implantation dosage, energy and current are chosen, during the ion implantation, so that concentration of implantation defects is less than a determined threshold, resulting in, within the thinned down thin film, a number of acceptor defects that is compatible with desired electrical properties of the thin film.

9. A method according to claim 8, wherein the ion implantation includes implanting ions chosen from among the following species: hydrogen and rare gases.

10. A method according to claim 8, wherein the fastening includes a bonding chosen from bonding by molecular adhesion via intermediate films or without intermediate films, bonding by reaction, metallic bonding, brazing or bonding by species diffusion.

11. A method according to claim 8, further comprising healing annealing of the implantation defects on the thin film.

12. A method according to claim 11, wherein the healing annealing is carried out before the thinning down the thin film.

13. A method according to claim 11, wherein the healing annealing is carried out after the thinning down the thin film.

14. Application of the method according to claim 8 to obtain a thin film of SiC, GaAs, GaN, diamond, or InP on a target substrate.
